(19) United States
(12) Patent Application Publication
(10) Pub. No.: US 2016/0284624 A1
(43) Pub. Date: Sep. 29, 2016

(54) HEAT SINK STRUCTURE, SEMICONDUCTOR DEVICE AND HEAT SINK MOUNTING METHOD

(71) Applicant: NEC CORPORATION, Tokyo (JP)

(72) Inventor: Yasushi YAMADA, Tokyo (JP)

(73) Assignee: NEC CORPORATION, Tokyo (JP)

(21) Appl. No.: 14/778,273

(22) PCT Filed: Mar. 17, 2014
(86) PCT No.: PCT/JP2014/001492

§ 371 Date: Sep. 18, 2015

(30) Foreign Application Priority Data
Mar. 21, 2013 (JP) 2013-058475

(51) Int. Cl. H01L 23/427; F28D 15/02; F28F 3/02; H01L 23/367; H01L 21/48

(52) U.S. Cl. CPC H01L 23/427; H01L 23/3672; H01L 21/4882; F28F 3/02; F28D 15/0275; F28F 2013/006

(57) ABSTRACT

[Problem to be solved]

In an electronic device that contains a plurality of heat-generating components, not all the heat-dissipation capabilities of the heat-generating components having heights different from each other are secured in a lump.

[Solution]

The heat sink structure of the invention includes: a first heat sink; a second heat sink having a protrusion in a lower part of a side surface thereof; a thermal conductivity substance sandwiched between a side surface of the first heat sink and a side surface of the second heat sink; and a flexible cushioning material sandwiched between the bottom surface of the first heat sink and the top surface of the aforementioned protrusion.

### TECHNICAL FIELD

The present invention relates to a heat sink structure and a mounting method thereof, and, more particularly, to a heat-dissipation technology of an electronic device containing a plurality of heat-generating components.

### BACKGROUND ART

In an electronic device that contains a plurality of heat-generating components, variation in height may exist in the heat-generating components. There have been cases where, when a position of a heat sink is optimized to the height of one heat-generating component, a cool sheet which is a solid thermal conductivity substance of a sheet shape is inserted between other heat-generating components of different heights and the heat sink, for a thermal connection between the other heat-generating components and the heat sink. A related cool sheet to be inserted between heat-generating components and a heat sink is disclosed in patent document 1.

In a cool sheet, flexibility and thermal conductivity is in a trade-off relationship generally. Although a cool sheet is originally solid and is difficult to be transformed even if force is added, it is possible to make it soft by adding an additive. However, on the other hand, the thermal conductivity of the cool sheet declines by influence of the additive.

### CITATION LIST

### Patent Literature

[PTL 1] Japanese Patent Application Laid-Open No. 1997-17923

### SUMMARY OF INVENTION

### Technical Problem

In the related cool sheet mentioned above, it is not realistic to prepare cool sheets having shapes conforming to respective heat-generating components. Therefore, a cool sheet which has flexibility to enable the sheet to be transformed according to the magnitudes of height variations of heat-generating components will be used. As a result, there has been a problem that the larger height variations of heat-generating components are, the more the heat-dissipation capability of a heat sink deteriorates.

An object of the present invention is to settle the above-mentioned problem. Specifically, the object of the present invention is to provide a heat sink structure which can secure heat-dissipation capabilities of a plurality of heat-generating components having different heights in a lump.

### Solution to Problem

A heat sink structure of the present invention includes: a first heat sink; a second heat sink having a protrusion in a lower part of a side surface thereof; a thermal conductivity substance sandwiched between a side surface of the first heat sink and a side surface of the second heat sink; and a flexible cushioning material sandwiched between the bottom surface of the first heat sink and the top surface of the aforementioned protrusion.

A heat sink mounting method of the present invention includes the steps of: mounting a first heat-generating component and a second heat-generating component; mounting a second heat sink on the second heat-generating component, the second heat sink being accompanied by a flexible cushioning material arranged on a top surface of a protrusion provided in a lower part of a side surface of the second heat sink and by a thermal conductivity substance arranged on a side surface of the second heat sink; and, by installing a first heat sink on the first heat-generating component, sandwiching the first thermal conductivity substance between a side surface of the first heat sink and the side surface of the second heat sink, and sandwiching the cushioning material between the bottom surface of the first heat sink and the top surface of the protrusion.

### Advantageous Effects of Invention

The present invention can secure heat-dissipation capabilities of a plurality of heat-generating components having different heights in a lump.

### BRIEF DESCRIPTION OF DRAWINGS

FIG. 1 is a sectional view when a second heat-generating component is tall in a first example.

FIG. 2 is a partially enlarged view of a joint between a first heat sink and a second heat sink.

FIG. 3 is a diagram showing an example of a planar relation between a first heat sink and a second heat sink.

FIG. 4 is a top view of a cushioning material.

FIG. 5 is a diagram showing a part of a production process of an electronic device having the heat sink structure of the first example.

FIG. 6 is a sectional view when a second heat-generating component is short in height in the first example.

FIG. 7 is a sectional view when a second heat-generating component is tall in a second example.

FIG. 8 is a segmentary view of a heat-pipe and a receiving part in a first heat sink.

FIG. 9 is a segmentary view of a heat-pipe and a second heat sink.

FIG. 10 is a sectional view when a second heat-generating component is short in height in the second example.

### DESCRIPTION OF EMBODIMENTS

Next, the first example of the present invention will be described in detail with reference to a drawing.

FIG. 1 is a sectional view when a second heat-generating component is tall in the first example. A first heat-generating component 2 and a second heat-generating component 5 are surface-mounted on a printed wiring board 8 fixed to a base 9. Meanwhile, in this figure, description will be made about a case where the second heat-generating component 5 is taller than the first heat-generating component 2 due to a variation in height of heat-generating components.

The first heat-generating component 2 is subject to force from a first heat sink 1 in a direction being pressed against the printed wiring board 8 via a thermal compound 3, which is a gelled thermal conductivity substance. Similarly, the second heat-generating component 5 is subject to force from a second heat sink 4 in a direction being pressed against the printed wiring board 8 via the thermal compound 3.

The first heat sink 1 is subject to force from a spring 10 in a direction being pressed against the base 9.

The second heat sink 4 is subject to force from the first heat sink 1 in a direction being pressed toward the base 9 via a flexible cushioning material 6. The first heat sink 1 and the second heat sink 4 are connected thermally via a thermal compound 7. Here, the thermal compound 7 is a gelled thermal conductivity substance containing silicone. There is a rubber material as an example of the cushioning material 6. Generally, a thermal conductivity is high in order of a heat sink, a thermal compound and a cushioning material.

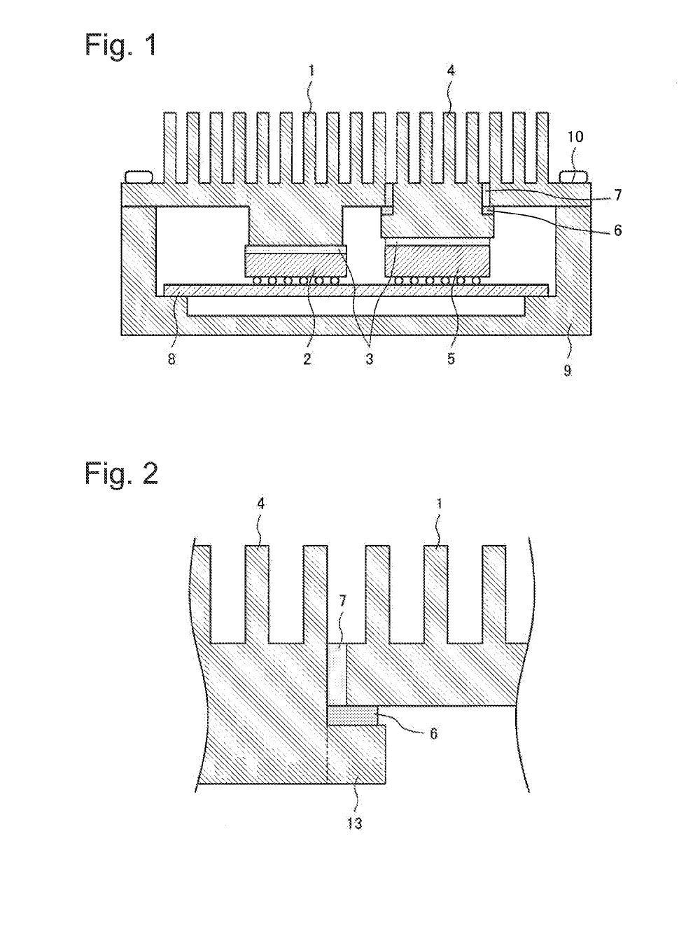

FIG. 2 is a partially enlarged view of a joint between the first heat sink and the second heat sink. As shown in this figure, a protrusion 13 is provided in a lower part of the joint surface of the second heat sink 4. In addition, the cushioning material 6 is attached in a manner that it is placed on the upper surface of the protrusion 13. The thermal compound 7 is sandwiched between a side surface of the first heat sink 1 and a side surface of the second heat sink 4.

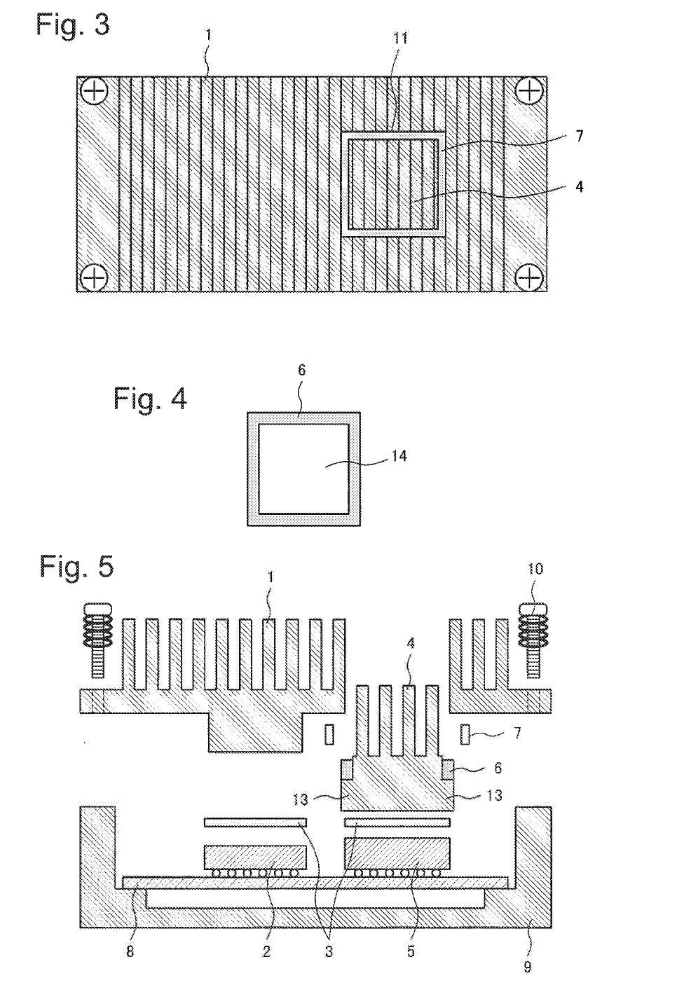

FIG. 3 is a diagram showing an example of a planar relation between the first heat sink and the second heat sink. As shown in this figure, the insertion portion 4 is inserted into an opening 11 provided in the first heat sink 1, and the thermal compound 7 is sandwiched between them. As a result, the first heat sink 1 and the second heat sink have close contact with each other via the thermal compound 7, and a thermal connection is realized. Meanwhile, shapes of the opening 11, the first heat sink 1 and the second heat sink 4 are not limited to the shapes shown in this figure, and may be changed according to the shape and the size of a heat-generating component, easiness of molding of members, other purposes and the like. For example, a joining part of a heat sink may be formed by one straight line.

FIG. 4 is a top view of the cushioning material 6. The cushioning material 6 is of a bezel shape and has an opening 14. The inside dimensions of the cushioning material 6 is made to be larger than the size of the second heat sink so that the first heat sink may pass through the opening 14. The outer size of the cushioning material 6 is made to be of a size close to the protrusion 13. The outer size of the cushioning material 6 may be larger than or may be smaller than the size of the protrusion 13. The inside dimension of the cushioning material 6 is smaller than the size of the protrusion 13.

FIG. 5 is a diagram showing a part of the production process of an electronic device having the heat sink structure of the first example.

First, the printed wiring board 8 is mounted on the base 9, and, further, the first heat-generating component 2 and the second heat-generating component 5 are mounted on the printed wiring board 8.

Next, the thermal compound 3 is applied to, within the upper surface of each of the first heat-generating component 2 and second heat-generating component 5, the whole of portions which come to touch the first heat sink or the second heat sink in a later process.

Next, the cushioning material 6 is attached so that it may be placed on the upper surface of the protrusion 13 provided in a lower part of the side surfaces of the second heat sink 4. After that, the thermal compound 7 is applied to, among the side surfaces of the second heat sink 4, the whole of portions that are being exposed.

Next, the second heat sink 4 is mounted on the second heat-generating component 5.

Next, the first heat sink 1 is mounted on the first heat-generating component. At that time, it is made such that the second heat sink fits in the opening 11 provided in the first heat sink. On this occasion, the thermal compound 7 touches the side surfaces inside the opening 11. By this, the second heat sink 4 and the first heat sink 1 are connected thermally. As a result, the temperature is equalized over the total heat sinks, and the heat-dissipation capabilities of internal components are secured.

Finally, the first heat sink 1 is fixed to the base 9 by the spring 10. As a result, the total heat sinks are pressed against the printed wiring board 8 and fixed.

Meanwhile, a method of application of the thermal compound 3 and the thermal compound 7 may be carried out manually, using a dispenser, or using an exclusive jig produced in advance.

When the second heat-generating component 5 is taller than the first heat-generating component 2, the second heat sink 4 becomes high according to the height of the second heat-generating component 5. A distance between the first heat sink 1 and the second heat sink 4 becomes small. At that time, the cushioning material 6 is sandwiched between the bottom surface of the first heat sink 1 and the top surface of the protrusion 13 in a manner being transformed and squeezed. As a result, the difference between the height of the second heat-generating component 5 and the second heat-generating component 2 that is tall is absorbed. The first heat sink 1 and the second heat sink 4 are connected thermally via the thermal compound 7.

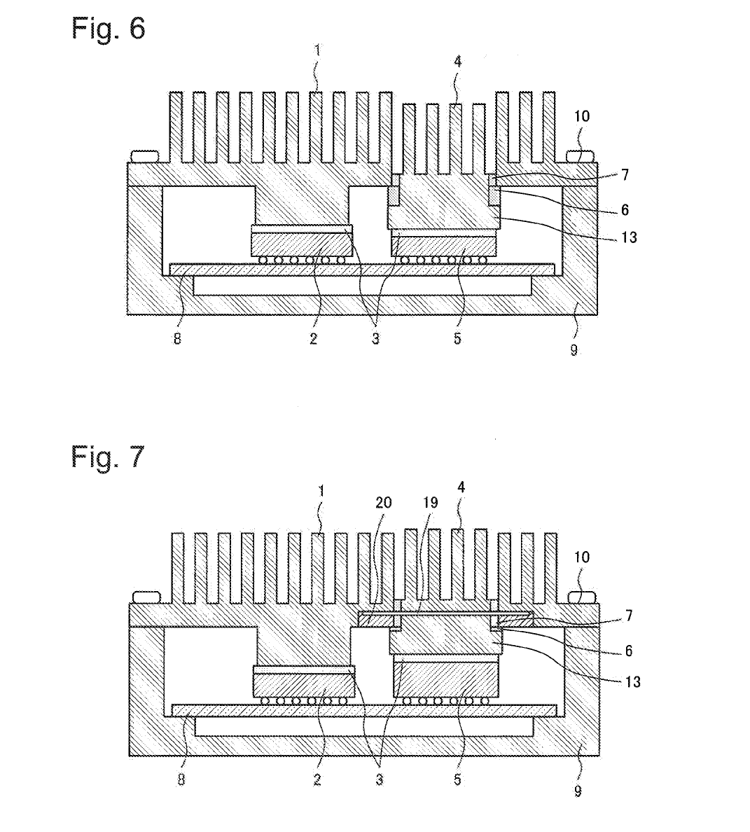

FIG. 6 is a sectional view when the second heat-generating component is short in height in the first example. According to the height of the second heat-generating component 16 of short in height, the second heat sink 4 becomes low. In this state, the distance between the first heat sink 1 and the second heat sink 4 is large. At that time, the cushioning material 6 is sandwiched between the bottom surface of the first heat sink 1 and the top surface of the protrusion 13 in a manner being hardly squeezed. As a result, the difference in the heights of the first heat-generating component 2 and the second heat-generating component 16 of short in height is absorbed. The first heat sink 1 and the second heat sink 4 are connected thermally via the thermal compound 7.

As mentioned above, included in this example are: the first heat sink 1; the second heat sink 4 having the protrusion 13 in a lower part of a side surface thereof; the thermal compound 7 sandwiched between a side surface of the first heat sink 1 and a side surface of the second heat sink 4; and the flexible cushioning material 6 sandwiched between the bottom surface of the first heat sink 1 and the top surface of the protrusion 13. By this, thermal connection with a heat sink can be realized for each individual heat-generating component. As a result, a temperature rise can be controlled and a longer operating life of a product is expected because heat-dissipation capabilities of internal components are secured.

Although, here, description has been made about the case where there are two heat-generating components, the present invention can secure heat-dissipation capabilities of no smaller than three heat-generating components by making it be of a structure in which two pieces or more of the above-mentioned second heat sink 4 are provided.

Next, the second example of the present invention will be described in detail with reference to a drawing. Meanwhile, about this second example, an identical code is attached to a component that is the same as that of the first exemplary embodiment mentioned above, and overlapped description of parts that are common with the first example is omitted.

FIG. 7 is a sectional view when a second heat-generating component 5 is tall in the second example. There is attached a heat-pipe 19 to a second heat sink 4, and a receiving part 20 to receive the heat-pipe 19 is provided in a first heat sink 4.

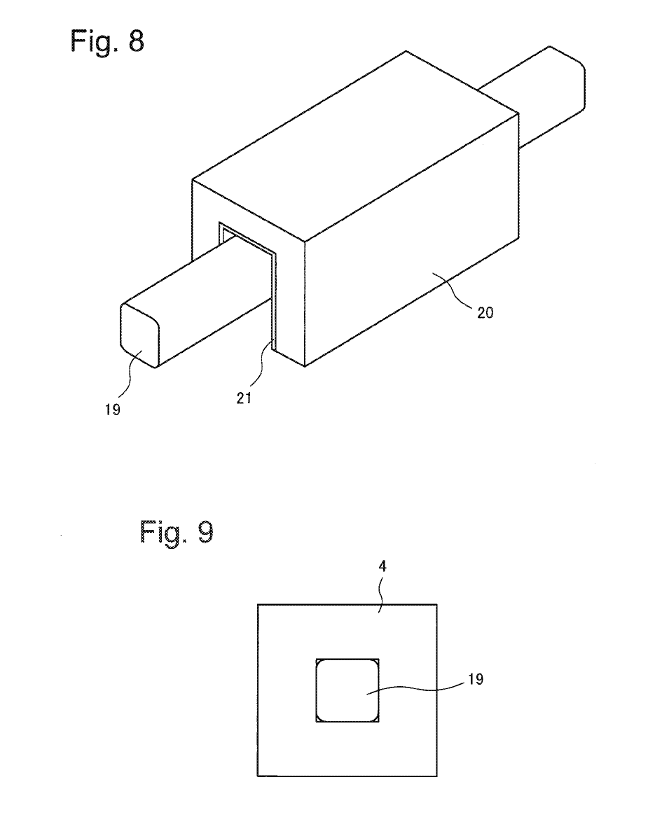

Meanwhile, a heat-pipe (Heat Pipe) is one of technologies and mechanisms to improve a thermal conductivity, and is a pipe in which a volatile liquid (Operating fluid or Working fluid) is enclosed in the pipe formed of a high thermal conductivity material. By heating one side in the pipe, and cooling the other side, the cycle of evaporation and condensation of the Operating fluid occurs and heat is transferred. FIG. 8 is a segmentary view of a heat-pipe and a receiving part in the first heat sink. The heat-pipe 19 moves in the vertical direction in the receiving part 20. The heat-pipe 19 and the inner wall of the receiving part 20 are thermally connected via a thermal compound 21. The up-and-down range of the thermal compound 21 is made to have a margin so that a thermal connection may be always maintained even when the heat-pipe is moved. The heat-pipe 19 performs heat conduction to the first heat sink 1 when the temperature of the second heat sink 4 is higher than the first heat sink 1.

FIG. 9 is a segmentary view of the heat-pipe and the second heat sink. In the second heat sink 4, the periphery of the heat-pipe 19 is enclosed, and the pipe is fixed. By this, the second heat sink 4 and the heat-pipe 19 are connected thermally.

By making it be the above-mentioned structure, a radiation path from the second heat-generating component 5 to the first heat sink 1 is reserved via the second heat sink 4 and the heat-pipe 19 in the second example. The thermal conductivity between the first heat sink 1 and the second heat sink 4 is improved by making it be a structure including the heat-pipe 19. In addition, a variation of the heights of heat-generating components can be absorbed by making the heat-pipe 19 movable up and down. The thermal compound 21 moves in conjunction with the movement of the heat-pipe 19 while changing its shape.

When the second heat-generating component 5 is taller than the first heat-generating component 2, the second heat sink 4 becomes high according to the height of the second heat-generating component 5. The distance between the first heat sink 1 and the second heat sink 4 becomes small. Along with this, the heat-pipe 19 moves in the receiving part 20 toward the upper direction.

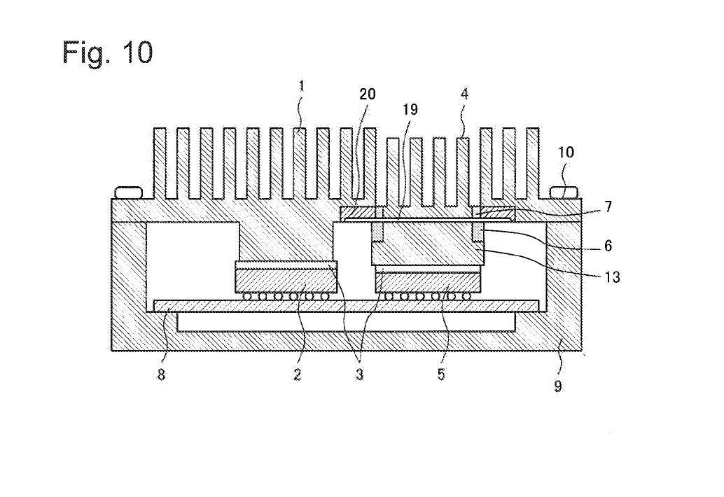

FIG. 10 is a sectional view when the second heat-generating component is short in height in the second example. According to the height of the second heat-generating component 16 that is short in height, the second heat sink 4 becomes low. In this state, the distance between the first heat sink 1 and the second heat sink 4 becomes small. Along with this, the heat-pipe 19 moves in the receiving part 20 toward the lower direction.

Although the present invention has been described with reference to examples above, the present invention is not limited to the above-mentioned examples. Various changes which a person skilled in the art can understand within the scope of the present invention can be performed in the composition and details of the present invention.

This application claims priority based on Japanese application Japanese Patent Application No. 2013-058475, filed on Mar. 21, 2013, the disclosure of which is incorporated herein in its entirety by reference.

### REFERENCE SIGNS LIST

1 First heat sink
2 First heat-generating component
3 Thermal compound
4 Second heat sink
5 Second heat-generating component
6 Cushioning material
7 Thermal compound
8 Printed wiring board
9 Base
10 Spring
11 Opening
13 Protrusion
14 Opening
16 Second heat-generating component of short in height
19 Heat-pipe
20 Receiving part
21 Thermal compound

1. A heat sink structure, comprising:
a first heat sink;
a second heat sink having a protrusion in a lower part of a side surface of the second heat sink;
a first thermal conductivity substance sandwiched between a side surface of the first heat sink and a side surface of the second heat sink; and
a flexible cushioning material sandwiched between a bottom surface of the first heat sink and a top surface of the protrusion.

2. The heat sink structure according to claim 1, wherein
the first heat sink has an opening, and wherein
the second heat sink has a shape fitting to the opening.

3. The heat sink structure according to claim 1, further comprising:
a heat-pipe provided inside the second heat sink, the heat-pipe exposing a part of the heat-pipe on at least one side surface of the second heat sink;
a receiving part provided inside the first heat sink, the receiving part receiving a part of the heat-pipe; and
a second thermal compound sandwiched between the heat-pipe and the receiving part.

4. A semiconductor device, comprising:
a substrate;
a first heat-generating component installed on the substrate;
a second heat-generating component installed on the substrate;
a first heat sink touching the first heat-generating component;
a second heat sink touching the first heat-generating component and having a protrusion in a lower part of a side surface of the second heat sink;
a first thermal conductivity substance sandwiched between a side surface of the first heat sink and a side surface of the second heat sink; and
a flexible cushioning material sandwiched between a base surface of the first heat sink and a top surface of the protrusion.

5. The semiconductor device according to claim 4, wherein
the first heat sink has an opening, and wherein
the second heat sink has a shape fitting to the opening.

6. The semiconductor device according to claim 4, further comprising:
a heat-pipe provided inside the second heat sink, the heat-pipe exposing a part of the heat-pipe on at least one side surface of the second heat sink;
a receiving part provided inside the first heat sink, the receiving part receiving a part of the heat-pipe; and
a second thermal compound sandwiched between the heat-pipe and the receiving part.

7. A heat sink mounting method, comprising the steps of:
mounting a first heat-generating component and a second heat-generating component;
mounting a second heat sink on the second heat-generating component, the second heat sink being accompanied by a flexible cushioning material arranged on a top surface of a protrusion provided in a lower part of a side surface of the second heat sink and by a thermal conductivity substance being arranged on a side surface of the second heat sink; and,
by installing a first heat sink on the first heat-generating component, sandwiching the first thermal conductivity substance between a side surface of the first heat sink and the side surface of the second heat sink, and sandwiching the cushioning material between a bottom surface of the first heat sink and the top surface of the protrusion.

8. The heat sink mounting method according to claim 7, wherein
the first heat sink has an opening, and wherein,
at a time of mounting the first heat sink, the second heat sink is made to fit in the opening.
